(19) United States
(12) Patent Application Publication
(10) Pub. No.: US 2006/0268651 A1
(43) Pub. Date: Nov. 30, 2006

(54) Memory apparatus and method

(76) Inventors: Douglas John Cutter, Fort Collins, CO (US); Christopher Craig Seib, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/138,019

(22) Filed: May 26, 2005

(51) Int. Cl. G11C 8/00

(52) U.S. Cl. 365/230.06

(57) ABSTRACT

A memory structure has a wordline coupled to at least one memory cell and a wordline driver coupled to the wordline. Further, the memory structure has a wordline chopper coupled to the wordline and configured to discharge the wordline, wherein the memory cell is coupled to the wordline between the wordline driver and the wordline chopper.

### RELATED ART

Integrated circuit (IC) memory structures, e.g., dynamic random access memory (DRAM), static random access memory (SRAM), and flash memory, typically comprise a large number of memory cells arranged in rows and columns, and such arrangement of memory cells is oftentimes referred to as an “array” of memory cells. A connected row of memory cells is typically referred to as a “wordline,” and a connected column of memory cells is typically referred to as a “bitline.” Each memory cell usually represents a single binary digit, hereinafter referred to as a “bit,” i.e., a logical “1” or a logical “0.” Additionally, the intersection of a wordline and a bitline in the array constitutes an address of a memory cell.

The logical configuration of each memory cell is typically consistent throughout the array and dictates its type of memory structure. For example, an SRAM cell usually comprises a plurality of transistors, e.g., four or six, and the storage element is formed via a flip-flop or latch, whereas the DRAM cell typically comprises a single transistor and the storage element comprises a capacitor.

The IC memory structure typically comprises peripheral circuitry, such as, for example, a wordline driver, a bitline driver, and/or a bitline receiver. During operation, to read a bit stored by a particular memory cell, a memory controller internal or external to the IC memory structure requests access to the memory cell on the IC memory structure. In so requesting, the memory controller provides data indicative of a wordline address to the wordline decoder/driver of the memory structure. The wordline decoder/driver decodes the address and activates the wordline by setting the wordline high, i.e., a logical “1.”

Once the wordline has been activated, the bitline receiver retrieves the data of each bitline associated each memory cell along the wordline that is currently activated. The bitline receiver then transmits the retrieved data associated with the memory cell address provided by the memory controller to the memory controller.

If the request is a write request, the memory controller provides a bit to be stored and an address associated with the particular memory cell that is to store the provided bit. The bitline driver drives a bitline corresponding to the provided memory cell address provided in the write request with the bit to be stored. The wordline driver then activates the wordline associated with the provided address high. When the wordline is driven high, the bitlines overpower the memory cell with the data, thereby saving the data in the memory cell.

During each memory cycle, certain timing rules are typically obeyed in order to ensure reliable operation. In this regard, the wordline must remain inactive while components of the memory cells are reinitialized to known values. The duration in the memory cycle during which the wordline remains inactive is oftentimes referred to as the “precharge interval.” The precharge interval is that portion of the memory cycle defined by the discharge of the wordline and the driving of a next wordline in response to another instruction received from the memory controller.

In this regard, if a precharge interval begins before the wordline is discharged, then erroneous data may be stored in the memory cells on the erroneously active wordline.

Additionally, with growing memory array sizes, the length of wordlines and the resulting resistance/capacitance (R/C) time constant along inherent to each wordline makes it challenging to provide enough time to precharge the bitlines to a known value after a read or write has occurred. It is especially difficult at the end of the wordline, because if the wordline has not discharged to a value substantially close to logical ‘0’ before precharging, the memory may inadvertently store the precharge value.

### SUMMARY OF THE DISCLOSURE

Generally, the present disclosure provides a system and method for improving precharge timing.

A memory structure in accordance with an embodiment of the present disclosure comprises a wordline coupled to at least one memory cell and a wordline driver coupled to the wordline. The memory structure also comprises a wordline chopper coupled to the wordline that is configured to discharge the wordline and the memory cell is coupled to the wordline between the wordline driver and the wordline chopper.

A memory access method in accordance with another embodiment of the present disclosure comprises the steps of transmitting a signal via a wordline driver through a wordline and initiating a discharge of the wordline at a plurality of points along the wordline.

### BRIEF DESCRIPTION OF THE DRAWINGS

The disclosure can be better understood with reference to the following drawings. The elements of the drawings are not necessarily to scale relative to each other, emphasis instead being placed upon clearly illustrating the principles of the disclosure. Furthermore, like reference numerals designate corresponding parts throughout the several views.

FIG. 1 is a block diagram illustrating a system in accordance with an exemplary embodiment of the present disclosure.

FIG. 2 is a block diagram of an exemplary memory structure such as is depicted in FIG. 1.

FIG. 3 is a circuit diagram of an exemplary memory cell such as is depicted in FIG. 2 employing an SRAM configuration.

FIG. 4 is a circuit diagram of an exemplary wordline chopper such as is depicted in FIG. 2.

FIG. 5 is a timing diagram illustrating exemplary waveforms produced by the memory structure such as is depicted in FIGS. 2-4 during operation.

FIG. 6 is block diagram illustrating another exemplary memory structure as depicted in FIG. 1.

FIG. 7 is a flow chart illustrating an exemplary architecture and functionality of the memory structure depicted in FIG. 2.

### DETAILED DESCRIPTION

Embodiments of the present disclosure generally pertain to systems and methods for precharging memory circuitry.

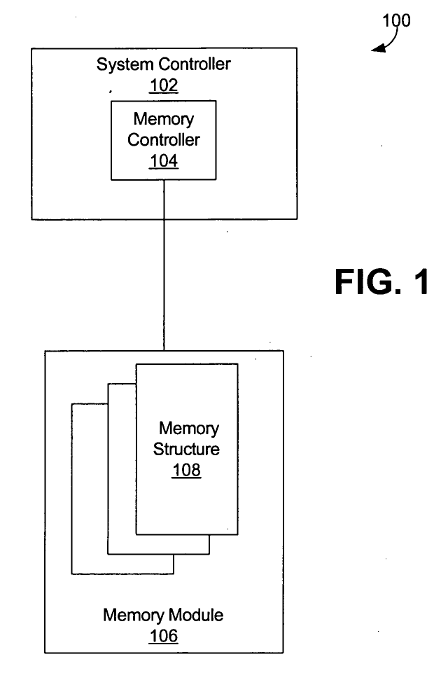

FIG. 1 depicts a system 100, e.g., a computer system, comprising a system controller 102 and a memory module 106. The system controller 102 comprises a memory controller 104, and the memory module 106 comprises at least one memory structure 108 in accordance with an embodiment of the present disclosure.

The memory structure 108 may employ, for example, dynamic random access memory (DRAM), static random access memory (SRAM), or flash memory. Other types of memory structures known in the art or future-developed are also possible in other embodiments.

Each memory structure 108 stores data that may be accessed by the system controller 102 via the memory controller 104. In this regard, the memory controller can read data from the memory structure 108 or write data to the memory structure during operation of the system 100.

The memory structure 108 is generally configured to receive from the memory controller 104 data indicative of an address that identifies a location for accessing a particular binary digit, e.g., a binary “1” or “0,” hereinafter referred to as a bit. The memory controller 104 may request access to the particular address in order to read a bit from the address identified or write a bit to the address identified. Thus, in addition to providing an address of a location in the memory structure 108, the memory controller 104 also provides an instruction to the memory structure 108, such as, for example, an instruction to write a particular bit to the address identified or read a particular bit from the address identified.

In accessing the address, either to write a bit to or read a bit from the identified address, states of various components that make up the memory structure 108 are modified. Therefore, in order to prepare for a next instruction and address from the memory controller 104, the memory structure 108 returns any modified components in the memory structure 108 to their initial states during a precharge interval, as described hereinabove.

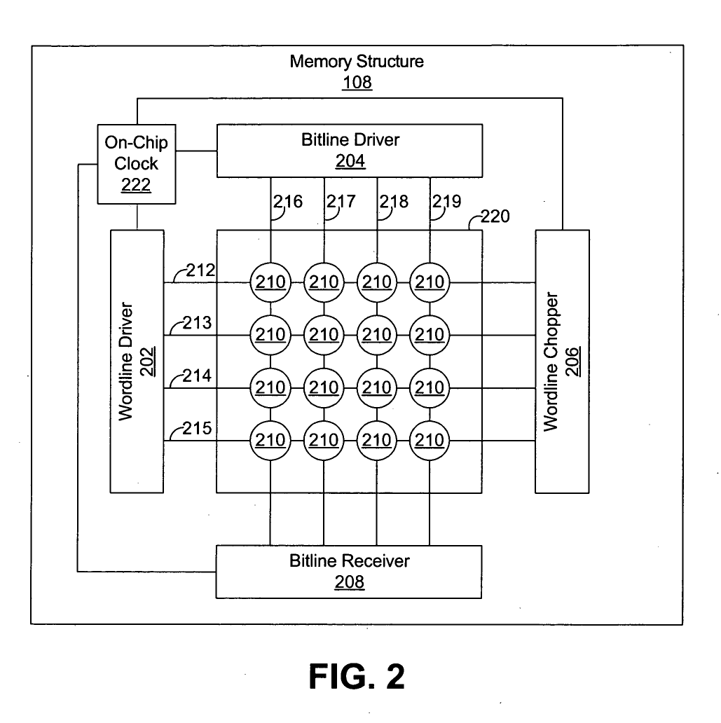

In one embodiment, the memory structure 108 discharges an end of a wordline being used to access the address. In discharging the signal, the memory structure 108 increases the duration of the precharge interval. Because the precharge interval is increased, the memory structure 108 can be used in memory modules having a large number of addresses available for access by the memory controller 104. In this regard, the longer the precharge interval, the more time the memory structure 108 has available for preparing itself for a next instruction and address. In other embodiments, the memory structure 108 discharges the wordline being used to access the identified address at a plurality of points along the wordline being used to access addresses available in the memory structure 108. Such is described in more detail with reference to FIGS. 2-5.

FIG. 2 depicts a memory structure 108 in accordance with an exemplary embodiment of the present disclosure. The memory structure 108 comprises a two-dimensional array 220 of memory cells 210. Each memory cell 210 in each row is connected via a wordline 212-215, and each memory cell 210 in each column is connected via a bitline 216-219. Furthermore, the intersection of each wordline 212-215 and bitline 216-219 constitutes an address of the corresponding memory cell 210.

The memory structure 108 further comprises peripheral circuitry, such as, for example, an on-chip clock 222, a wordline driver 202, a bitline driver 204, and a bitline receiver 208. Additional and/or different peripheral circuitry is possible in other embodiments.

The wordline driver 202 is connected to each memory cell 210 via the wordlines 212-215. The bitline driver 204 is connected to each memory cell 210 via the bitlines 216-219, and the bitline receiver 208 is connected to each memory cell 210 via the bitlines 216-219. Furthermore, the on-chip clock 222 provides a clock signal to the wordline driver 202, the bitline driver 204, and the bitline receiver 208. Such clock signal provided to the peripheral circuitry enumerated is used by each component to synchronize and operate the various operations performed on the chip. For example, the wordline driver 202 uses the on-chip clock 222 to clock data received from the memory controller 104 and to clock the wordlines 212-215 when the wordline driver 202 drives one of the wordlines 212-215 high, i.e., to a logical “1.”

During operation, the memory structure 108 receives data from the memory controller 104 (FIG. 1) indicative of a row associated with one of the wordlines 212-215 and data indicative of at least one of the bitlines 216-219. Additionally, the memory structure 108 receives data indicating whether data is to be read or written to the memory cell 210 corresponding to the address associated with the received wordline and bitline. Further, if the data indicates a write instruction, the memory structure 108 further receives data indicative of bit values that are to be written to the provided address.

For example, the array 220 illustrated in FIG. 2 is a simple four-by-four memory cell array 220. In this regard, each of the four rows in the array 216 may have associated with it a unique identifier. For example, row one associated with wordline 212 is identified by “00,” row two associated with wordline 213 is identified by “01,” row three associated with wordline 214 is identified by “10,” and row four associated with wordline 215 is identified by “11.” Note that in other embodiments there can be more memory cells that are accessed via a greater number of wordlines and bitlines. However, for simplicity of discussion, the array 216 is shown comprising a four-by-four cell array, which constitutes sixteen addressable memory cells 210.

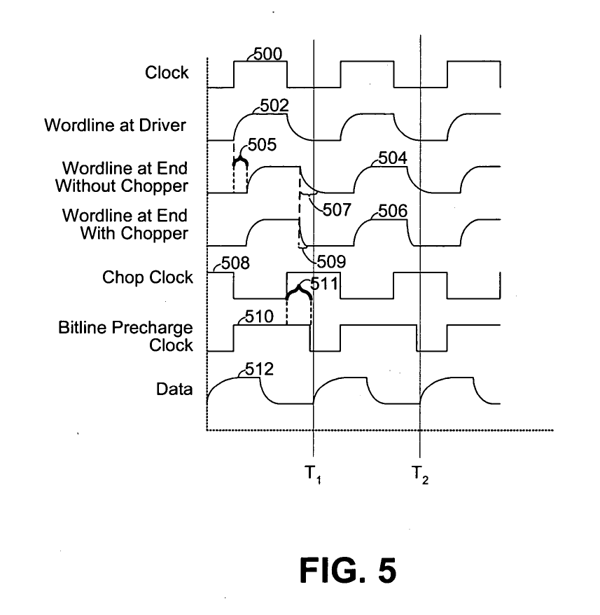

If the data indicates a read instruction, the wordline driver 202 decodes the data indicative of the address associated with the wordline that is to be selected for reading. Note that, as described herein, the memory controller 104 (FIG. 1) provides an address indicative of the location of the cell that is to be read. The wordline driver 202 then drives the wordline associated with the indicated address high. An exemplary wordline signal is shown in detail with reference to FIG. 5.

In the example provided hereinabove, if the wordline driver 202 decodes the data received from the memory controller 104 indicative of the row address and translates the data into a “00,” the wordline driver 202 drives the wordline 212 high, i.e., to a logical “1.”

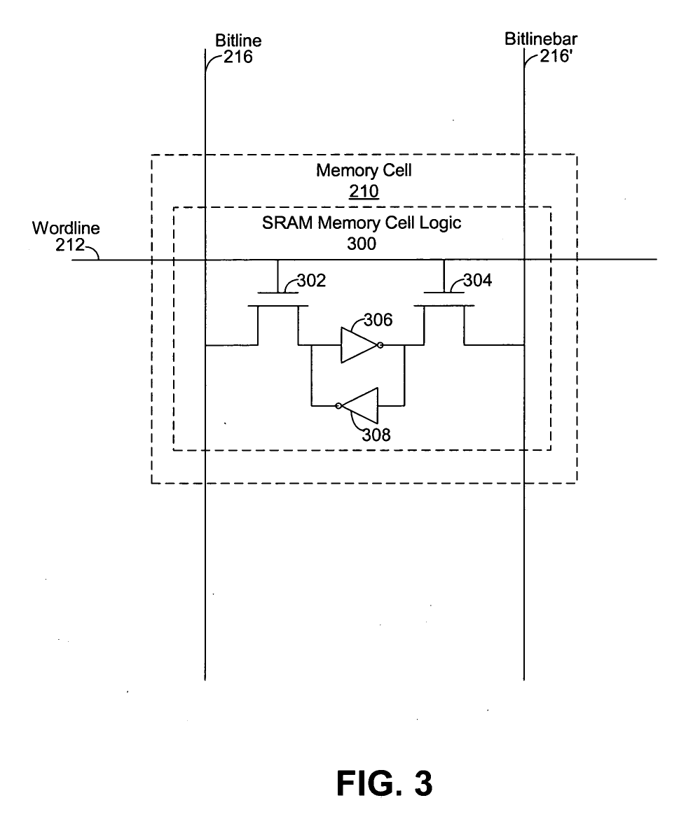

By driving the wordline 212 high, the row associated with the wordline 212 is activated. Therefore, the memory cells 210 that make up the row associated with the wordline 212 are activated. Such activation and access are described in more detail with reference to exemplary circuitry illustrated in FIG. 3-5.

Generally, however, if the instruction is a read instruction, the bitline receiver 208 receives that portion of the data indicative of the address which indicates the bitline 216-219 corresponding to the memory cell 210 from which the memory controller 104 is requesting data. The bitline receiver 208 retrieves the value of each memory cell 210 that is currently activated from each bitline 216-219. The bitline receiver 208 then transmits the retrieved value associated with the indicated bitline to the memory controller 104.

If the instruction is a write instruction, the bitline driver 204 receives data from the memory controller 104 (FIG. 1) indicative of a column associated with one of the bitlines 216-219 and the bit value that is to be written to the memory cell 210 associated with the indicated bitline. As described hereinabove, the array 220 illustrated in FIG. 2 is a simple four-by-four memory cell array 216. In this regard, each of the four columns in the array 216 may have associated with it a unique data bit.

The bitline driver 204 decodes the data indicative of the column address associated with the bitline 216-219 that is to be written to, and drives the bitline 216-219 to the bit value provided. In the example provided, if the bitline driver 204 decodes the data indicative of the column address and translates the data into a “00,” the bitline driver 204 drives a signal indicative of the bit value onto the bitline 216.

Once the data is driven onto the indicated bitline 216-219, the wordline driver 202 activates a wordline 212-215 associated with the row address provided corresponding to the write instruction received. When the wordline is activated, the bit value placed on the bitline 216-219 overpowers the memory cell 210 associated with the wordline 212-215, and the bit value is written to the memory cell 210.

In this regard, if the instruction is a read instruction, the bitline receiver 208 reads a bit from an active memory cell 210 and completes an instruction request from the memory controller 104. If the instruction is a write instruction, the bitline driver 204 writes a bit value to a bitline 216-219, the wordline driver 202 activates the wordline 212-215, and the bit value is written to a memory cell 210, thereby completing a write request from the memory controller 104.

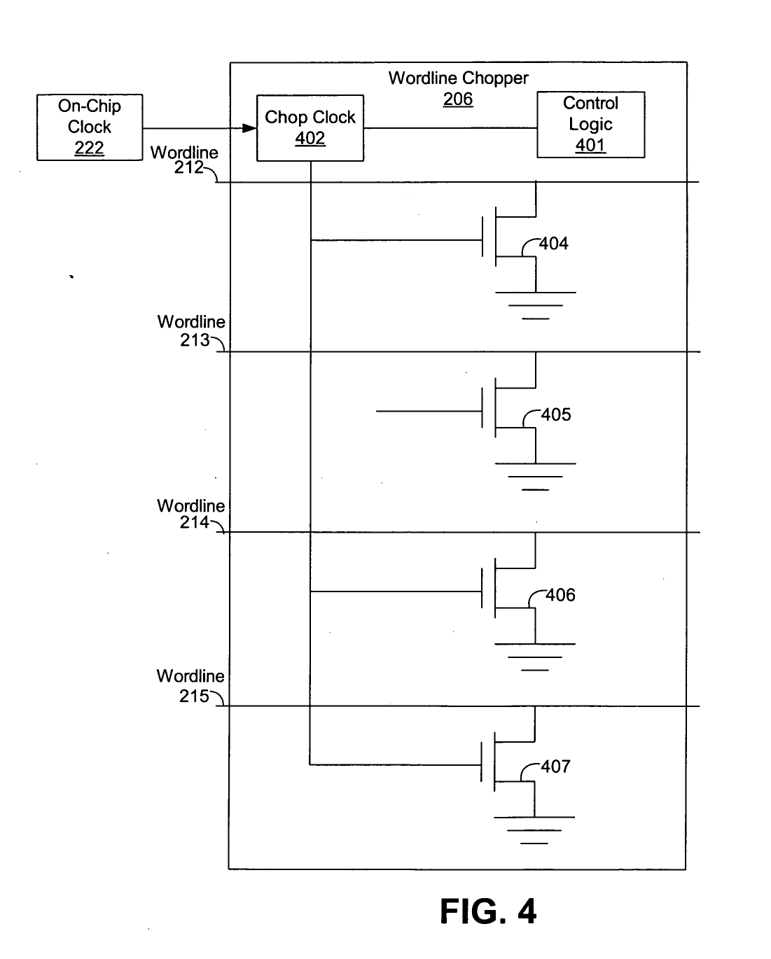

In order to proceed with a next instruction and a corresponding address from the memory controller 104, the memory structure 108 initiates components contained within the memory cells 210 to their initial states. Initial states of particular components contained within the memory cells are dependent upon the type of memory cell employed, e.g., DRAM, SRAM, or flash memory. Exemplary initial states are described in more detail with reference to an SRAM memory cell in the discussion related to FIGS. 3 and 4. Furthermore, an “initial state” of a component refers to a particular state of a circuit that allows reliable initiation of a subsequent instruction that follows a previous instruction. The memory structure 108 performs such initialization during the precharge interval, as described with reference to FIG. 1. Note that the longer the precharge interval, the more time the memory structure 108 has to initialize the memory cells 210 to their initial (or known) states.

Further, the precharge interval occurs from the point in a memory access cycle when the wordline 212 previously being driven is discharged and the next wordline 212 identified by the row address of the next memory cell 210 that is to be accessed is driven. Note that a “memory access cycle” with reference hereto refers to a cycle comprising receiving a memory address, accessing a memory cell identified by the address, and writing data to the memory cell (if the instruction corresponding to the received address corresponds to a write instruction) or transmitting data to the memory controller 104 (if the instruction corresponding to the received address corresponds to a read instruction).

The memory structure 108 in accordance with the present disclosure further comprises a wordline chopper 206. The wordline chopper 206 is preferably clocked via a clock signal derived from the on-chip clock 222. However, the clock signal that drives the wordline chopper 206 is more tightly controlled in that the number of factors that might cause a delay of the clock signal are reduced and/or eliminated. For example, the clock signal might be more tightly routed so as to reduce the length that the clock signal travels to the wordline chopper 206.

Generally, the wordline chopper 206 discharges to ground the wordline 212-215 that is being driven by the wordline driver 202. However, instead of waiting for wordline driver 202 to discharge the wordline 212-215 from the start of the wordline 212-215, the wordline chopper 206 discharges the wordline 212. In one embodiment, the wordline chopper 206 might discharge the wordline 212-215 intermediate of two memory cells 210. In another embodiment, the wordline chopper 206 might discharge the wordline 212-215 at a plurality of locations across the wordline 212-215.

By discharging the wordline 212-215 as described hereinabove, the memory chopper 206 can increase the precharge interval by initiating the precharge interval at an earlier point during the memory cycle, i.e., as soon as the wordline chopper 206 discharges the wordline 212-215 at the end, instead of waiting for the wordline driver 202 to discharge the wordline 212-215.

Furthermore, due to the resistance and/or capacitance (R/C) characteristics of the wordline 212-215 there is an inherent delay at the end of the wordline 212-215 where the wordline 212-215 is connected to the wordline chopper 206. Therefore, by discharging the wordline 212-215 at the end of the wordline 211, i.e., at the wordline chopper 206, the wordline chopper 206 effectively more quickly discharges the wordline 212-215 by pulling the wordline 212-215 down at the end of the wordline 212-215.

As described herein, the memory structure 108 can be of varying types, such as, for example, a DRAM, an SRAM, or flash memory. In this regard, each of these types of memory structures comprises differing electronic components that make up the memory cell 210.

In order to further illustrate the wordline chopper 206 of the present disclosure, a detailed description of the present disclosure corresponding to a memory cell structure based upon SRAM architecture is now described with reference to FIGS. 3-5.

FIG. 3 depicts exemplary circuitry of an SRAM memory cell 210 of an exemplary memory structure 108 of FIG. 2.

The memory cell 210 depicted in FIG. 3 comprises SRAM memory cell logic 300. The SRAM memory cell logic 300 comprises two transistors 302 and 304 and two inverters 306 and 308. Note that if the memory structure 108 in FIG. 2 is SRAM, each memory cell 210 employs the SRAM memory cell logic 300 depicted in FIG. 3. However, if the memory structure 108 is another type of memory, e.g., DRAM, then the logic 300 would comprise different logic architecture for the memory cell 210. The SRAM architecture is shown for illustrative purposes only. Further note that the SRAM memory cell logic 300 may be implemented in software, hardware, or a combination thereof.

The memory cell 210 illustrated in FIG. 3 is representative of the memory cell 210 at the intersection of the wordline 212 and the bitline 216. However, in an SRAM memory structure, each bitline comprises two connections, a bitline 216 and a bitlinebar 216′. As described herein, bitline 216 supplies the bit and bitlinebar 216′ supplies its complement.

If the memory cycle being executed is a read cycle, i.e., the memory controller 104 is requesting a read of the memory cell 210, then the wordline 212 is driven high during selection of the wordline 212 by the wordline driver 202. When the wordline 212 is driven high, the transistors 302 and 304 enable the memory cell 210 and the value stored in the cell 210 is driven onto bitline 216 and its complement onto bitlinebar 216′.

If the memory cycle being executed is a write cycle, i.e., the memory controller 104 is requesting to write to the selected cell, then the bitline driver 208 drives bitline 216 and bitlinebar 216′ with the desired bit that is to be written to the memory cell 210, which is provided by the memory controller 104 in the write instruction. Once the bit value is driven onto bitline 216 and its complement onto bitlinebar 216′, the wordline 212 is driven high by the wordline driver 202, and the desired bit is stored in the memory cell 210.

Notably, prior to a read or a write instruction, bitline 216 and bitlinebar 216′ are preferably initialized high, i.e., to a logic “1,” because the transistors 302 and 304 are capable of pulling down the bitlines 216 and 216′ more quickly as opposed to pulling them up. Therefore, in an SRAM configuration, during the precharge interval, as described herein, each bitline 216-219 is preferably initialized high so that a read can occur if requested by the memory controller 104. Further note that as the array 220 (FIG. 2) increases in array size, i.e., the wordlines 212-215 are longer and there are more and more bitlines 216-219, it takes more time for the bitline driver 204 to initialize the bitlines 216-219 during the precharge interval. Therefore, the longer the precharge interval, the more time the bitline driver 204 has to initialize the bitlines 216-219.

As described herein, the precharge interval occurs from the point in the memory cycle when the wordline 212-215 is discharged to the initiation of a new cycle by the memory controller 104. Further, as indicated herein, the memory structure 108 discharges the wordline 212-215 sooner than if the wordline 212-215 were discharged by the wordline driver 202. In this regard, when the wordline driver 202 discharges the wordline 212-215, there is a delay as the discharge propagates from the wordline driver 202 to the end of the wordline 212-215. Therefore, as described herein, the memory structure 108 further comprises the wordline chopper 206 that discharges the end of the wordline 212-215, so that the precharge interval is increased, and the bitline driver 204 has increased time to precharge the bitlines 216-219 high, i.e., to a digital “1.”

An exemplary wordline chopper is now described with reference to FIG. 4.. FIG. 4 depicts an exemplary wordline chopper 206. The wordline chopper 206 is shown as connected at the end of each wordline 212-215.

The wordline chopper 206 comprises control logic 401 and a chop clock 402. Further, the wordline chopper 206 comprises a plurality of transistors 404-407. Preferably, there is a transistor for each wordline 212-215. The number of transistors may be less or more in other embodiments. Although the wordline chopper 206 is shown as implemented in hardware, the wordline chopper 206 may be implemented in hardware, software, or a combination thereof.

As indicated herein, the chop clock 402 preferably clocks the transistors 404-407 with a clock signal that does not exhibit a delay that is inherent in the signal transmitted by the wordline driver 202 through the wordline 212-215. In this regard, the wordline 212-215 inherently produces a delay due to several factors including the resistance and/or capacitance characteristics of the wire making up the wordline 212-215, the length of the wordline 212-215, and the number of memory cells 210 attached to the wordline 212-215. For example, as the length of the wordline 212-215 increases, the delay inherent in the wordline 212-215 increases. Note that a typical delay may be, for example, 50 picoseconds, depending upon the length of the wordline 212-215. To the contrary, however, the chop clock 402 may only exhibit a delay of 10 picoseconds. Therefore, the memory chopper 206 may be able to discharge the wordline 212-215 at the end of the wordline 212-215 approximately 40 picoseconds quicker than if the wordline driver 202 initiates discharge.

The control logic 401 drives the chop clock 402 and the chop clock activates one of the transistors 404-407 corresponding to the active wordline. Note that the control logic 401 may determine which wordline 212-215 is presently active.

When the chop clock 402 activates a transistor 402-407, the signal present on the corresponding wordline 212-215 is discharged to ground by the transistor 404-407, respectively. Further, because the chop clock 402 is faster than the clock of the wordline driver 202 thereby exhibiting shorter clock cycles, the wordline 212-215 is discharged sooner at the end of the wordline 212-215 than it would have been if discharge of the wordline 212-215 depended upon discharge initiated by the wordline driver 202. Discharging the wordline 212-215 from the wordline driver 202 and the wordline chopper 206 substantially simultaneously or otherwise can decrease the time required to discharge an RC limited wordline 212-215.

FIG. 5 depicts a set of waveforms that further illustrates the memory structure 108 of the present disclosure.

In this regard, waveform 500 depicts an exemplary representation of the wordline driver clock signal. Note that the waveforms of FIG. 5 are illustrated in approximately two-and-a-half clock cycles, as indicated by T₁ and T₂.

At the leading edge of a positive clock cycle of the clock waveform 500, the wordline driver 202 (FIG. 2) drives the wordline 212-215 high, i.e., to a logical “1.” Waveform 502 shows the wordline waveform 502 at the wordline driver 202. Waveform 504 illustrates the waveform at the end of the wordline 212-215 when the wordline chopper 206 (FIG. 2) is not employed in order to increase the precharge time in the memory cycle. As shown, there is a slight delay 505 that results from propagation of the signal along the wordline 212-215.

Waveform 506 illustrates the waveform at the end of the wordline 212-215 when the wordline chopper 206 is employed. In this regard, the waveform 504 indicates a differential 507 at the falling edge of the waveform 504. In contrast, the differential 509 indicated when the chopper 206 is employed is less that the differential 507 when the chopper is not employed. When the chopper 206 is employed, the falling edge of the wordline 212-215 is pulled back, and therefore terminates sooner than the waveform 504. Thus, the wordline 212-215 is discharged more quickly when the wordline chopper 206 is used. Because the wordline 212-215 is discharged more quickly, the precharge interval can begin sooner thereby allowing more time for the bitline driver 204 to precharge the bitlines 216-219.

As described hereinabove, the chop clock 402 drives the transistors 404-407, and the clock cycle of the chop clock is faster than that of the bitline precharge clock, as described hereinabove. Contrasting the chop clock waveform 508 and the precharge clock 510 illustrates the relationship between the wordline chopper 206 and the precharge interval. In this regard, when the chop clock 402 goes high, the end of the wordline 212-215 is pulled low, thereby cutting short the wordline 212. The falling edge of the bitline precharge clock is thus delayed, as indicated by the differential 511 between the rising edge of the chop clock waveform 508 and the falling edge of the bitline precharge clock waveform 510.

Waveform 512 illustrates an exemplary bit waveform, which is dependent upon the data that is read or written by the bitline receiver 208 or the bitline driver 204, respectively.

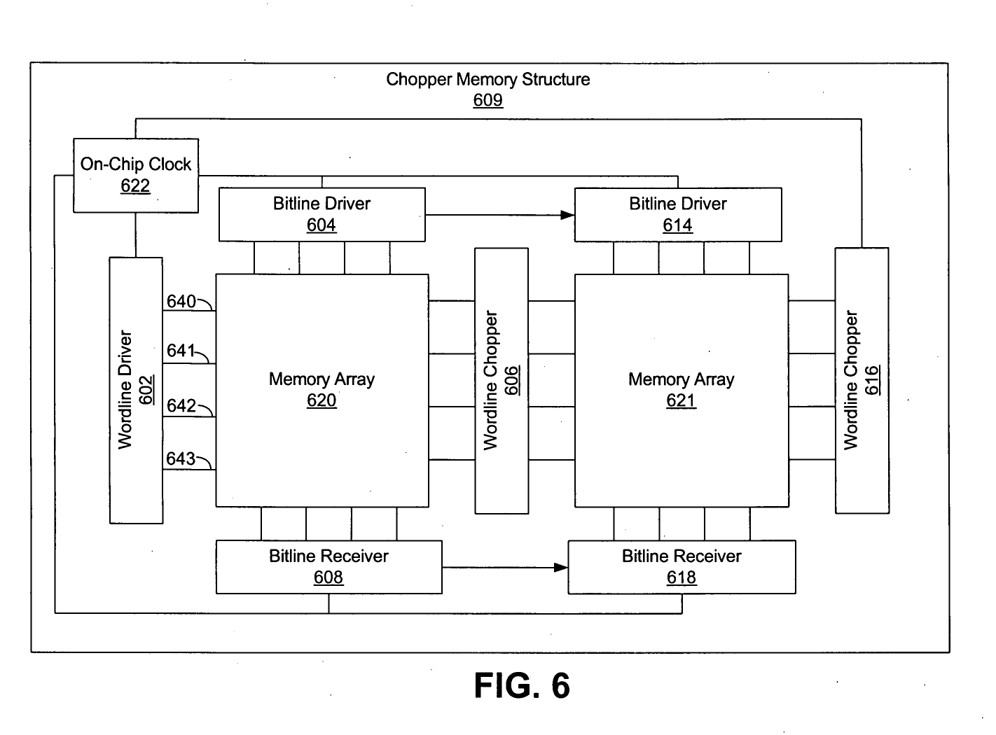

FIG. 6 depicts another embodiment of a memory structure 609. The memory structure 609 comprises a plurality of memory sub-arrays 620 and 621. Furthermore, the memory structure 609 comprises an infrastructure of peripheral memory, e.g., a wordline driver 602, bitlines drivers 604 and 614 for each of the sub-arrays 620 and 621, and bitline receivers 608 and 618 for each of the memory arrays 620 and 621.

The memory structure 609 operates substantially like the memory structure 108 described herein with reference to FIG. 2. However, in addition to the peripheral circuitry enumerated hereinabove, the memory structure 609 comprises a plurality of wordline choppers 606 and 616. In this regard, in addition to the wordline chopper 616 that is connected at the end of the wordlines 640-643, the memory structure 609 further comprises a wordline chopper 606 intermediate the memory arrays 620 and 621. Therefore, in addition to discharging an active wordline 640-642 at the end of each wordline 640-642, the wordline chopper 606 also discharges the active wordline 640-642 at a point in the memory structure that separates to memory sub-arrays 620 and 621. The number of memory arrays can be increased in other embodiments and respective wordline choppers that may be effective in increasing the precharge interval by discharging the wordlines more readily.

In other embodiments, the wordline 640-642 may extend through a large array or through a large number of sub-arrays. In this regard, any number of memory choppers 606 may be distributed along an extraordinarily long wordline, and the distribution of the choppers 606 along the wordline would ensure rapid discharge of the wordline regardless of its length.

For example, the memory structure may comprise five sub-arrays along the wordline having a plurality of memory cells 210 (FIG. 210). The memory structure may further comprise peripheral circuitry corresponding to each of the five sub-arrays. In this regard, each sub-array may be associated with a wordline chopper, such that there are five wordline choppers, and each wordline chopper may be connected between every two of the five sub-arrays, such that there are five wordline choppers.

In operation, the wordline driver 602 activates an indicated wordline 630-633. In accordance with a chop clock (not shown) corresponding to each wordline chopper 606 and 616, as described herein with reference to FIG. 4, each wordline chopper 606 and 616 would drive the wordline 640-642 to ground, thereby discharging the wordline 640-642 prior to when the wordline 640-642 would be discharged by the wordline driver 602.

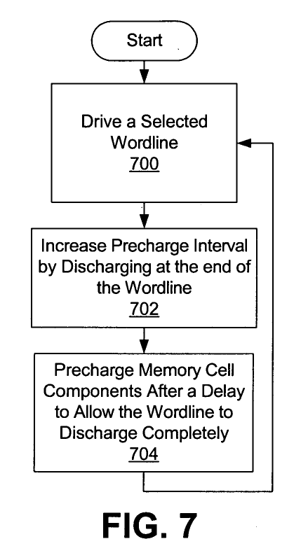

FIG. 7 is a flowchart depicting an exemplary architecture and functionality of a memory structure 108 of the present disclosure.

The memory structure 108 (FIG. 1) drives a selected wordline 212-215 (FIG. 2) as indicated in step 700. The memory structure 108 preferably drives the selected wordline 212-215 at the rising edge of a clock cycle initiated by an on-chip clock 222 (FIG. 2). Note that driving of the wordline 212-215 may be prior to a read of a memory cell 210 or subsequent to a bitline 216-219 being provided with bit values by a bitline driver 208.

The memory structure 108 then discharges the wordline 212-215 at the end of the wordline 212-215, as indicated in step 704. A chop clock 402 that is derived from the on-chip clock 222 preferably drives discharge of the wordline 212-215. As described herein, the delay in the generated clock signal is typically much less than the delay inherent in the wordline. Factors that contribute to the delay in the wordline 212-215 include the series resistance and capacitance inherent in the wordline 212-215, the length of the wordline 212-215, and the number of memory cells 210 that are connected to the wordline 212-215. Each of these factors can contribute to the delay in the wordline 212-215 illustrated by the differences shown in FIG. 5 between waveform 802, the wordline 212-215 initiated at the driver 202 and waveform 804, the wordline 212-215 at the end of the wordline. Such discharge of the wordline 212-215 at the end of the wordline 212-215 by the wordline chopper 206 as well as at the beginning of the wordline 212-215 by the wordline driver 202 pulls the wordline 212-215 down more quickly. Thus, the precharge interval is extended.

The memory structure 108 then precharges memory cell components after a slight delay to allow the wordline 212-215 to discharge completely. In the example of the SRAM provided, the bitline driver 204 (FIG. 2) precharges bitline 216a (FIG. 3) and bitline′ 216b (FIG. 3) to a logical high prior to receiving a next instruction and address from the memory controller 104 (FIG. 1).

1. A memory structure, comprising:
a wordline coupled to at least one memory cell;
a wordline driver coupled to the wordline; and
a wordline chopper coupled to the wordline and configured to discharge the wordline, wherein the memory cell is coupled to the wordline between the wordline driver and the wordline chopper.

2. The memory structure of claim 1, wherein the wordline driver is configured to discharge the wordline.

3. The memory structure of claim 2, wherein the wordline comprises a first end and a second end, and wherein the wordline driver is coupled to the first end and the wordline chopper is coupled to the second end.

4. The memory structure of claim 1, wherein the wordline driver is configured to select the wordline by transmitting a logical signal through the wordline based upon a first clock signal, the transmitted signal enabling access to the memory cell.

5. The memory structure of claim 4, wherein the wordline driver is configured to initiate discharge of the logical signal based upon the first clock signal.

6. The memory structure of claim 5, wherein the wordline chopper is further configured to discharge the logical signal based upon a second clock signal, the second clock signal initiating discharge of the wordline prior to discharge of the logical signal initiated by the wordline driver.

7. The memory structure of claim 6, wherein the wordline chopper comprises a transistor, the transistor activated by the second clock signal.

8. The memory structure of claim 7, wherein when the transistor is activated by the second clock signal, the transistor discharges the logical signal to a ground.

9. The memory structure of claim 1, wherein the memory cell is a static random access memory (SRAM) cell, and wherein the SRAM cell comprises a first and second transistor, the first and second transistors connected to a first and second bitline such that when the wordline driver activates the memory cell, the first and second transistor write a first value and a second value of the first and second bitlines in the selected memory cell or place data indicative of contents of the memory cell on the first and second bitlines.

10. A memory access method, comprising the steps of:
transmitting a signal via a wordline driver through a wordline; and
initiating a discharge of the wordline at a plurality of points along the wordline.

11. The memory access method of claim 10, wherein the wordline is coupled to at least one memory cell and wherein the memory cell is coupled to the wordline between the wordline driver and one of the plurality of points along the wordline.

12. The memory access method of claim 10, wherein the wordline is coupled to a memory cell and wherein the memory cell is coupled to the wordline between a first point and a second point of the plurality of points along the wordline.

13. The memory access method of claim 10, wherein the wordline is coupled to a plurality of memory cells and wherein each of the plurality of memory cells is coupled to the wordline between at least two of the plurality of points along the wordline.

14. The memory access method of claim 10, wherein the wordline comprises a first end and a second end and wherein the wordline driver is coupled to the first end and at least one of the plurality of points is coupled to the second end.

15. The memory access method of claim 14, further comprising the step of discharging the signal from the first end.

16. The memory access method of claim 15, further comprising the step of discharging the signal from the second end.

17. A memory structure, comprising:
a wordline driver coupled to a wordline; and
a wordline chopper coupled to the wordline configured to discharge the wordline, the wordline coupled to at least two sub-arrays of memory cells, the wordline chopper coupled to the wordline between the two sub-arrays.

18. A memory structure, comprising:
a wordline driver coupled to a wordline; and
a wordline chopper coupled to the wordline configured to discharge the wordline between a plurality of pairs of sub-arrays of memory cells, the wordline chopper coupled to the wordline between each pair of sub-arrays.

19. The memory structure of claim 18, wherein the wordline driver comprises discharging logic configured to discharge the wordline.

20. The memory structure of claim 19, further comprising a wordline driver clock, the wordline driver clock configured to time activation and discharging of the wordline.

21. The memory structure of claim 20, further comprising a chopper clock, the chopper clock configured to time activation and discharging of the wordline and to activate discharge of the wordline prior to discharge activated by the wordline driver clock.

22. The memory structure of claim, wherein each memory cell is a static random access memory (SRAM) cell, and each SRAM cell comprises a first and second transistor, the first and second transistors connected to a first and second bitline corresponding to each cell such that when the wordline driver activates each memory cell, the first and second transistors write the value of the first and second bitlines in the selected memory cell or place data indicative of contents of the memory cell on the first and second bitlines.

23. A memory access method, comprising the steps of:
transmitting a signal via a wordline driver through a wordline, the wordline coupled to a plurality of sub-arrays, each sub-array comprising a plurality of memory cells; and
discharging the wordline between at least a portion of the sub-arrays via a wordline chopper coupled to the wordline between the portion of sub-arrays.

24. A memory structure, comprising:
a wordline coupled to at least one memory cell;
a wordline driver coupled to the wordline; and
means for discharging the wordline, wherein the memory cell is coupled to the wordline between the wordline driver and the means for discharging.
